(19) United States
(12) Patent Application Publication
(10) Pub. No.: US 2014/0140016 A1
(43) Pub. Date: May 22, 2014

(54) POWER METAL MESH AND SEMICONDUCTOR MEMORY DEVICE AND METHOD INCLUDING THE SAME

(71) Applicant: SK HYNIX INC., Icheon-si Gyeonggi-do (KR)

(72) Inventors: Jun Ho LEE, Icheon-si Gyeonggi-do (KR); Sung Woo HAN, Icheon-si Gyeonggi-do (KR); Ic Su OH, Icheon-si Gyeonggi-do (KR); Boo Ho JUNG, Icheon-si Gyeonggi-do (KR); Sun Ki CHO, Icheon-si Gyeonggi-do (KR); Yang Hee KIM, Icheon-si Gyeonggi-do (KR); Tae Hoon KIM, Icheon-si Gyeonggi-do (KR)

(73) Assignee: SK HYNIX INC., Icheon-si Gyeonggi-do (KR)

(21) Appl. No.: 13/845,568

(22) Filed: Mar. 18, 2013

(30) Foreign Application Priority Data
Nov. 20, 2012 (KR) 10-2012-0131437

(51) Int. Cl. H03H 7/01; H05K 1/18

(52) U.S. Cl. CPC H03H 7/0115; H05K 1/18
USPC 361/748; 333/175; 174/260

(57) ABSTRACT

A power metal mesh and a semiconductor memory device including the same are provided. As the power metal mesh configured to reduce noise coupling generated between adjacent chips disposed on an interposer, a band stop filter unit including an inductor and a capacitor coupled in parallel is disposed between the adjacent chips to effectively reduce the noise coupling of a specific frequency band generated between the adjacent chips.

### CROSS-REFERENCES TO RELATED APPLICATION

This application claims priority under 35 U.S.C. 119(a) to Korean application number 10-2012-0131437, filed on Nov. 20, 2012, in the Korean Intellectual Property Office, which is incorporated herein by reference in its entirety.

### BACKGROUND OF THE INVENTION

1. Technical Field

The inventive concept generally relates to a power metal mesh, a semiconductor memory device, and method including the same, and more particularly, to a power metal mesh for reducing noise coupling and a semiconductor memory device and method including the same.

2. Related Art

With the rapid development of semiconductor memory technology, high integration and high performance of packaging technology for semiconductor integrated devices have been increasingly required. Therefore, technology for a three-dimensional (3D) structure in which a plurality of semiconductor chips are vertically stacked has been variously developed other than a 2D structure in which semiconductor chips in which integrated circuits (ICs) are implemented are two-dimensionally disposed on a printed circuit board (PCB) using wires or bumps.

Such a 3D structure may be implemented through a stack package technology and the semiconductor chips which are vertically mounted are electrically coupled to each other through metal wires or through silicon vias (TSVs) and mounted on a board for semiconductor package.

On the other hand, when through electrodes may be formed using the TSVs, thinned, light, short, and minute semiconductor packages with high performance are promoted by conventionally applying a silicon (or glass) interposer between a PCB and ICs.

However, since various kinds of semiconductor chips such as system ICs, memories, and image sensors are mounted on the interposer, power noise coupling (or ground noise coupling) between adjacent chips is frequently caused.

In the related art, as a method for reducing the noise coupling on the silicon interposer, a decoupling capacitor implemented using a MOS transistor capacitor is used.

However, when the decoupling capacitor is implemented, a silicon active region has to be ensured and thus it goes against high integration and additionally the fabrication cost is greatly increased.

Further, when the interposer is implemented with silicon, if an active layer is not formed and only a metal layer may be formed to reduce the fabrication cost, it is very vulnerable to the power noise coupling unless a power domain is separated.

Therefore, in these fields, there is an urgent need for a power metal mesh structure capable of reducing the power noise coupling or the ground noise coupling which is generated on the silicon interposer advantageously used to the stack package technology.

### SUMMARY

According to various embodiments, there is provided a power metal mesh. The power metal mesh may include a band stop filter unit formed on an interposer to be disposed among a plurality of adjacent chips electrically coupled to each other and formed by extending a power metal layer configured to supply power the chips.

In various embodiments, there is provided a semiconductor memory device including a power metal mesh. The semiconductor memory device may include: an interposer; a plurality of adjacent chips formed on the interposer and electrically coupled to each other; a power metal layer configured to supply power to the chips; and a power metal mesh disposed among the adjacent chips and formed by extending the power metal layer.

In various embodiments, there is provided a method of reducing noise coupling generated between chips including electrically connecting a plurality of adjacent chips, formed on an interposer, to each other, supplying power to the chips through a power metal layer; and disposing a power metal mesh between the adjacent chips, wherein the power metal mesh is formed by extending the power metal layer.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a view illustrating a structure of a power metal mesh in a semiconductor memory device according to first embodiments of the inventive concept;

FIG. 2 is a view illustrating a structure of a power metal mesh in a semiconductor memory device according to second embodiments of the inventive concept;

FIG. 3 is a view illustrating a structure of a power metal mesh in a semiconductor memory device according to third embodiments of the inventive concept; and

FIG. 4 is a view illustrating a power noise transfer characteristic curve when the power metal meshes according to the various embodiments of the inventive concept is applied.

### DETAILED DESCRIPTION

Hereinafter, various embodiments will be described in greater detail with reference to the accompanying drawings.

Various embodiments are described herein with reference to cross-sectional illustrations that are schematic illustrations of the various embodiments (and intermediate structures). As such, variations from the shapes of the illustrations as a result, for example, of manufacturing techniques and/or tolerances, are to be expected. Thus, the various embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

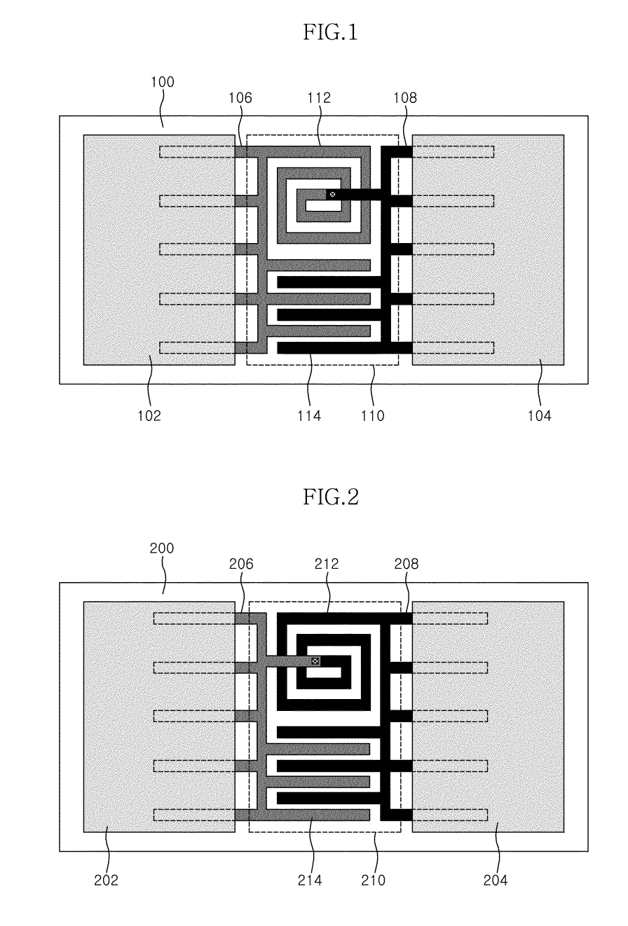

FIG. 1 illustrates a structure of a power metal mesh of a semiconductor memory device according to first embodiments of the inventive concept.

Referring to FIG. 1, a silicon interposer 100 is provided and a chip A 102 configured to perform a designed function and a chip B 104 sharing a power metal mesh with the chip A 102 may be formed to be spaced from each other at a predetermined distance.

A power metal layer 106 configured to supply power to the chip A 102 may be formed in a right end of the chip A 102 and a power metal layer 108 configured to supply power to the chip B 104 may be formed in a left end of the chip B 104. At this time, the power metal layers may be entirely disposed in the chip A 102 and the chip B 104. Here, the power metal layer is represented as the power metal layer 106 in the right end of the chip A 102 or the power metal layer 108 in the left end of the chip B 104 does not indicate a total power metal layer formed in the chip A 102 and the chip B 104, but merely indicates a power metal mesh illustrated in drawings.

As the power metal mesh configured to reduce noise coupling generated between the chip A 102 and the chip B 104 disposed on the silicon interposer 100, a band stop filter unit 110 including an inductor 112 and a capacitor 114 may be formed.

Since the chip A 102 and the chip B 104 disposed on the silicon interposer 100 share the power metal layer, the noise coupling is inevitably generated between the chip A 102 and the chip B 104. Therefore, in the embodiments, the band stop filter unit 110 may be formed as a structure for reducing the noise coupling generated between the chip A 102 and the chip B 104.

The structure of the band stop filter unit 110 will be described in more detail. The band stop filter unit 110 may include the inductor 112 and the capacitor 114 coupled in parallel. The inductor 112 and the capacitor 114 may be formed using a metal layer which is mutually shared by the chip A 102 and the chip B 104.

The inductor 112 and the capacitor 114 may be formed in a structure in which inductance and capacitance are maximized, respectively. Therefore, in the first embodiments, the inductor 112 may be implemented in a spiral type. More specifically, the power metal layer 106 extending from the chip A 102 may be disposed in a spiral type and the power metal layer 108 extending from the chip B 104 may be coupled to an end of the power metal layer 106 extending from the chip A 102 through a contact so that the inductor 112 may be entirely or substantially entirely formed in a spiral type. The capacitor 114 may be formed so that the power metal layers 106 and 108 extending the respective chip A 102 and chip B 104 are alternatively disposed.

The band stop filter unit 110 including the inductor 112 and the capacitor 114 coupled in parallel may be coupled to the power metal layers between the chip A 102 and the chip B 104 to reduce the noise coupling generated between the chip A 102 and the chip B 104.

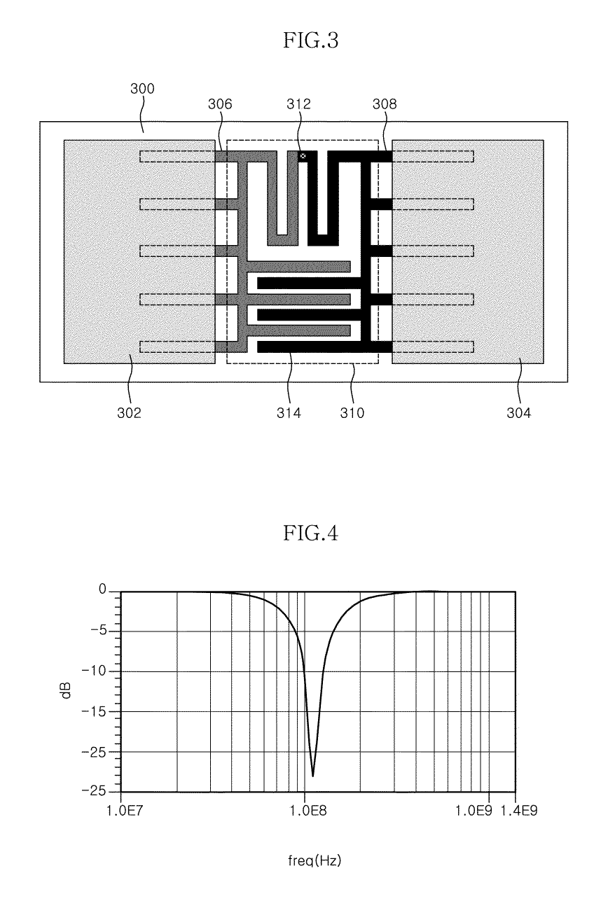

FIGS. 2 and 3 illustrate structures of power metal meshes in the semiconductor memory devices according to second embodiments and third embodiments of the inventive concept.

Only a band stop filler unit disposed between adjacent chips in structures of the power metal meshes in the semiconductor memory devices according to the second and third embodiments illustrated in FIGS. 2 and 3 may be different from the structure of the power metal mesh according to the first embodiments illustrated in FIG. 1. Therefore, the second and third embodiments will be described by focusing on the band stop filter unit different from the structure of the first embodiments.

FIG. 2 illustrates the structure of the power metal mesh in the semiconductor memory device according to the second embodiments.

Referring to FIG. 2, a chip A 202 and a chip B 204 may be formed on a silicon interposer 200. A power metal layer 206 configured to supply power to the chip A 202 may be formed in a right end of the chip A 202 and a power metal layer 208 configured to supply power to the chip B 204 may be formed in a left end of the chip B 204.

As a power metal mesh configured to reduce noise coupling generated between the chip A 202 and the chip B 204 disposed on the silicon interposer 200, a band stop filter unit 210 including an inductor 212 and a capacitor 214 may be formed.

The structure of the bands stop filter unit 210 will be described in more detail. The band stop filter unit 210 may include the inductor 212 and the capacitor 214 coupled in parallel to each other. The inductor 212 and the capacitor 214 may be formed to have a structure in which inductance and capacitance can be maximized. Therefore, in the second embodiments, the inductor 212 may be implemented in a spiral type. However, unlike the first embodiments, the power metal layer 208 extending from the chip B 204 may be disposed in a spiral type and the power metal layer 206 extending from the chip A 202 may be coupled to an end of the power metal layer 208 extending from the chip B 204 through a contact so that the inductor 212 may be entirely or substantially entirely formed in a spiral type. Like the first embodiments, the capacitor 214 may be formed to alternately dispose the power metal layers 206 and 208 extending from the chip A 202 and the chip B 204, respectively.

The band stop filter unit 210 including the inductor 212 and the capacitor 214 coupled in parallel may be coupled to the power metal layers between the chip A 202 and the chip B 204 to reduce the noise coupling generated between the chip A 202 and the chip B 204.

FIG. 3 illustrates the structure of the power metal mesh in the semiconductor memory device according to the third embodiments of the inventive concept.

Referring to FIG. 3, a chip A 302 and a chip B 304 may be formed on a silicon interposer 300. A power metal layer 306 configured to supply power to the chip A 302 may be formed in a right end of the chip A 302 and a power metal layer 308 configured to supply power to the chip B 304 may be formed in a left end of the chip B 304.

As a power metal mesh configured to reduce the noise coupling generated between the chip A 302 and the chip B 304 disposed on the silicon interposer 300, a band stop filter unit 310 including an inductor 312 and a capacitor 314 may be formed.

A structure of the band stop filter unit 310 will be described in more detail. The band stop filter unit 310 may include the inductor 312 and the capacitor 314 coupled in parallel. The inductor 312 and the capacitor 314 may be formed in a structure in which inductance and capacitance can be maximized. Therefore, when the inductor 312 may be formed in the third embodiments, unlike the spiral type inductors in the first and second embodiments, the inductor 312 may be formed in a coil structure. More specifically, the power metal layer 306 extending from the chip A 302 and the power metal layer 308 extending from the chip B 304 may be disposed in a zigzag type so that the inductor 312 may be formed in a coil type. A coil unit including the power metal layer 306 extending the chip A 302 and a coil unit including the power metal layer 308 extending from the chip B 304 may be coupled to each other through a contact so that the inductor 312 may be entirely or substantially entirely formed in the coil structure. Like in the first and second embodiments, the capacitor 314 may be formed to alternately dispose the power metal layers 306 and 308 extending from the chip A 302 and the chip B 304, respectively.

The band stop filter unit 310 including the inductor 312 and the capacitor 314 coupled in parallel may be coupled to the power metal layers between the chip A 302 and the chip B 304 to reduce the noise coupling generated between the chip A 302 and the chip B 304.

FIG. 4 illustrates a power noise transfer characteristic curve when the power metal meshes according to the various embodiments of the inventive concept are applied.

Referring to FIG. 4, an x-axis indicates a frequency band in hertz and a y-axis indicates a frequency level in decibels. It can be seen from FIG. 4 that power noise is greatly reduced in a specific frequency band, for example, a frequency band of about 1.0E8.

Therefore, when there are two chips from which noise coupling has to be reduced, the power metal mesh (that is, the band stop filter unit) as illustrated in FIGS. 1 to 3 is disposed between the two chips to effectively reduce the noise coupling of the specific frequency band generated between the two chips.

As described above, as a power metal mesh configured to reduce the noise coupling generated between adjacent chips disposed on the silicon interposer, the band stop filter unit including the inductor and the capacitor coupled in parallel is disposed. As a result, the noise coupling of the specific frequency band generated between the adjacent chips can be effectively reduced.

On the other hand, the metal structure of the inductor and the capacitor constituting the band stop filter unit according to the inventive concept may be designed according to a desired noise frequency band to be cut off. Therefore, the structure of the inductor and capacitor may be changed other than the structure of the inductor and capacitor illustrated in FIGS. 1 to 3. Further, the various embodiments illustrate the structure in which the capacitor is coupled in parallel to a lower end of the inductor, but it is possible to form the structure in which the inductor is in parallel to a lower end of the capacitor.

Further, the various embodiments have described the power metal mesh, but the inventive concept may be similarly applied to the ground metal mesh.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A power metal mesh, comprising:
a band stop filter unit formed on an interposer to be disposed among a plurality of adjacent chips electrically coupled to each other and formed by extending a power metal layer configured to supply power the chips.

2. The power metal mesh of claim 1, wherein the band stop filter unit includes an inductor and a capacitor coupled in parallel to each other.

3. The power metal mesh of claim 2, wherein the inductor has a spiral structure in which the power metal layer is disposed in a spiral type.

4. The power metal mesh of claim 2, wherein the inductor has a coil structure in which the power metal layer is disposed in a coil type.

5. The power metal mesh of claim 2, wherein the band stop filter unit has a structure in which the capacitor is coupled in parallel to a lower end of the inductor.

6. The power metal mesh of claim 2, wherein the band stop filter unit has a structure in which the inductor is coupled in parallel to a lower end of the capacitor.

7. The power metal mesh of claim 2, wherein the capacitor is formed so that the power metal layers extending from their respective chips are alternatively disposed.

8. The power metal mesh of claim 2, wherein the inductor and the capacitor are formed in a structure in which inductance and capacitance are maximized, respectively.

9. A semiconductor memory device, comprising:
an interposer;
a plurality of adjacent chips formed on the interposer and electrically coupled to each other;
a power metal layer configured to supply power to the chips; and
a power metal mesh disposed between the adjacent chips and formed by extending the power metal layer.

10. The semiconductor memory device of claim 7, wherein the power metal mesh includes a band stop filter unit including an inductor and a capacitor coupled in parallel.

11. The semiconductor memory device of claim 8, wherein the inductor has a spiral structure in which the power metal layer is disposed in a spiral type.

12. The semiconductor memory device of claim 8, wherein the inductor has a coil structure in which the power metal layer is disposed in a coil type.

13. The semiconductor memory device of claim 8, wherein the band stop filter unit has a structure in which the capacitor is coupled in parallel to a lower end of the inductor.

14. The semiconductor memory device of claim 8, wherein the band stop filter unit has a structure in which the inductor is coupled in parallel to a lower end of the capacitor.

15. The semiconductor memory device of claim 10, wherein the capacitor is formed so that the power metal layers extending from their respective chips are alternatively disposed.

16. The semiconductor memory device of claim 10, wherein the inductor and the capacitor are formed in a structure in which inductance and capacitance are maximized, respectively.

17. A method of reducing noise coupling generated between chips comprising:
electrically connecting a plurality of adjacent chips, formed on an interposer, to each other;
supplying power to the chips through a power metal layer; and
disposing a power metal mesh between the adjacent chips,
wherein the power metal mesh is formed by extending the power metal layer.

18. The method of claim 17, wherein the power metal mesh includes a band stop filter unit including an inductor and a capacitor coupled in parallel.

19. The method of claim 18, wherein the inductor has a spiral structure in which the power metal layer is disposed in a spiral type or a coil structure in which the power metal layer is disposed in a coil type.

20. The method of claim 18, wherein the band stop filter unit has a structure in which the capacitor is coupled in parallel to a lower end of the inductor or a structure in which the inductor is coupled in parallel to a lower end of the capacitor.
